(19) United States
(12) Patent Application Publication
(10) Pub. No.: US 2026/0282490 A1
(43) Pub. Date: Sep. 17, 2026

(54) SEMICONDUCTOR DEVICE HAVING TWO STEP SOURCE OR DRAIN CONTACT

(71) Applicant: Taiwan Semiconductor Manufacturing Co., Ltd., Hsinchu (TW)

(72) Inventors: Chun-Yuan CHEN, Hsinchu (TW); Chao-Hsun WANG, Hsinchu (TW); Fu-Kai YANG, Hsinchu (TW); Huan-Chieh SU, Hsinchu (TW); Kuo-Cheng CHIANG, Hsinchu (TW); Chi-Hao WANG, Hsinchu (TW)

(73) Assignee: Taiwan Semiconductor Manufacturing Co., Ltd., Hsinchu (TW)

(21) Appl. No.: 19/300,345

(22) Filed: Aug. 14, 2025

Related U.S. Application Data
(60) Provisional application No. 63/772,287, filed on Mar. 14, 2025.

(51) Int. Cl. H10D 64/23; H01L 23/528; H10D 30/00; H10D 62/10; H10D 84/01; H10D 84/83

(52) U.S. Cl. CPC H10D 64/258; H10D 64/257; H10D 84/0149; H10D 84/832; H10W 20/43; H10D 30/502; H10D 62/121

(57) ABSTRACT

The present disclosure describes a semiconductor device having a two-step source or drain contact structure. The two-step source or drain contact structure includes a first part on a source or drain structure of a transistor, and a second part on the first part and extending laterally beyond the first part toward a source or drain structure of another transistor.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2 show a semiconductor structure including a two-step source or drain contact structure according to example implementations herein.

FIG. 3 shows a process of forming a semiconductor structure according to example implementations herein.

FIGS. 4, 4A, 5, 6 show a semiconductor structure at various stages of the process of FIG. 3 according to example implementations herein.

FIG. 7 illustrates a semiconductor structure including a source or drain flyer structure according to example implementations herein.

### DETAILED DESCRIPTION

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features are formed in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one implementation,” “an implementation,” “an example implementation,” “exemplary,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of one skilled in the art to effect such feature, structure or characteristic in connection with other implementations whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some implementations, the terms “about” and “substantially” can indicate a value of a given quantity that varies within 20% of the value (e.g., ±1%, ±2%, ±3%, +4%, +5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a first source or drain (S/D) structure of a first nanostructure transistor can be electrically connected to a second S/D structure of a second nanostructure transistor at different sides of a gate structure through source or drain (S/D) contact structures, via structures, first level metal lines (M0), first level metal vias (V0), and second level metal lines (M1). However, the metal routing for one source/drain contact (MD) structure to another source/drain contact (MD) structure in different rows may occupy multiple signal tracks, which increases the cell height. Additionally, contact structures of a third nanostructure transistor may get closer to S/D structures of an adjacent fourth nanostructure transistor due to an overlay shift. The decreased distance between the source/drain contact structures and adjacent S/D structures may cause time-dependent dielectric breakdown (TDDB) and reduce the reliability of the semiconductor device.

The disclosure herein includes implementations that the metal routing for a source/drain contact (MD) to another source/drain contact in different rows of transistors occupies a metal track in only one metal layer, e.g., the first metal layer (MO). In some implementations, a source or drain contact (MD) includes two parts, referred to herein as “two-step source or drain contact,” the first part of the source or drain (S/D) contact or “MD1” is on and electrically coupled to a first source or drain (S/D) structure, and the second part of the S/D contact or “MD2” is on the first part and extends from the first part to an adjacent second source or drain structure that is not coupled to a S/D contact (MD) structure. The second part of the S/D contact structure is also referred to as a “S/D contact flyer” as it flies over at least one S/D structure that it is not connected to. There is a gap between the S/D contact flyer structure (MD2) and the second S/D structure so that the S/D contact flyer (MD2) structure and the second S/D structure are separated from one another.

The second part of the source or drain contact structure (MD2) is coupled to a via (VD) structure. For example, the via (VD) structure is on the second part of the S/D contact structure. In some implementations, a first end portion of the second part of the S/D contact (MD) structure is on the first part of the S/D contact (MD1) structure, and the via (VD) structure is on a second end portion of the second part of the S/D contact (MD2) structure. The second end portion is opposite to the first end portion. The via (VD) structure is coupled to a wire line in the first metal layer (M0). As such, the two-step S/D contact structure is formed in the middle end of line (MOL) procedures and because of the S/D contact flyer structure (MD2), only one level of the back end of line (BOL) metallization feature is used to achieve the connections between S/D structures of different transistor lines.

The nanostructure transistor may be a gate all around (GAA) transistor. The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

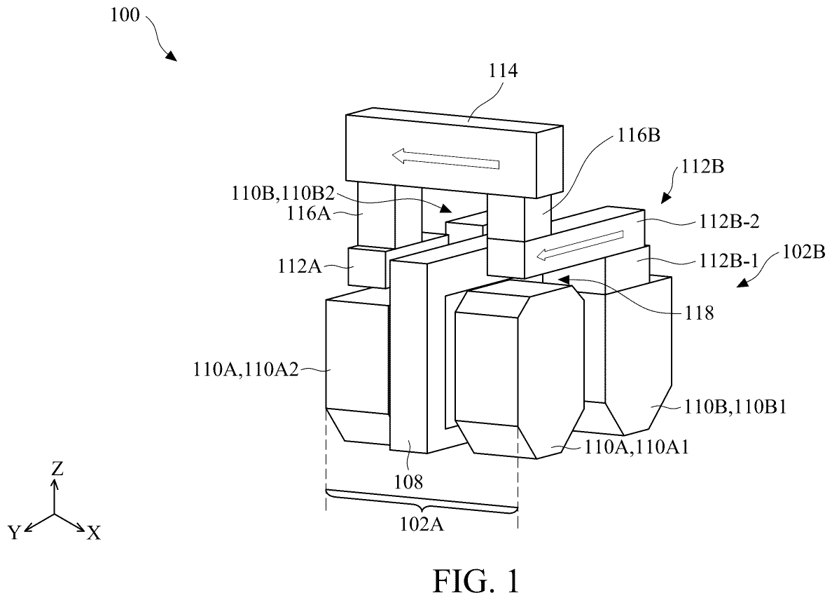

FIG. 1 illustrates, in a projection view a portion of a semiconductor device 100 including a two-step source or drain contact structure, in accordance with some implementations. As shown in FIG. 1, the portion of semiconductor device 100 can include transistors 102A, 102B. In some implementations, transistors 102A, 102B can include nanostructure transistors. The nanostructure transistors can include finFETs, gate-all-around field effect transistors (GAA FETs), nanosheet transistors, nanowire transistors, multi-bridge channel transistors, nano-ribbon transistors, and other similar structured transistors. For example, the nanostructure transistors can provide a channel in a stacked nanosheet/nanowire configuration.

In some implementations, transistors 102A, 102B each can be n-type field-effect transistors (NFETs) or p-type field-effect transistors (PFETs). In some implementations, any one of transistors 102A, 102B can be a same type of transistor, an NFET or a PFET, or can be different types of transistors. In some implementations, transistors 102A and 102B can be in a cell. Though FIG. 1 shows two transistors, semiconductor device 100 can have any number of transistors. In addition, semiconductor device 100 can be incorporated into an IC through the use of other structural components, such as conductive vias, conductive lines, dielectric layers, passivation layers, and interconnects, some of which are not shown for simplicity. The discussion of elements of transistors 102A, 102B with the same annotations applies to each other, unless mentioned otherwise. And like reference numerals generally indicate identical, functionally similar, and/or structurally similar elements.

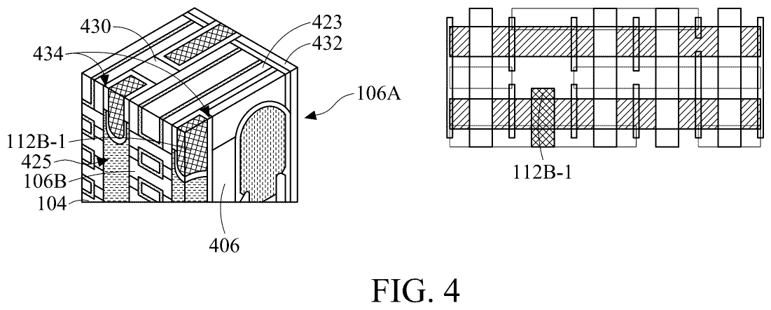

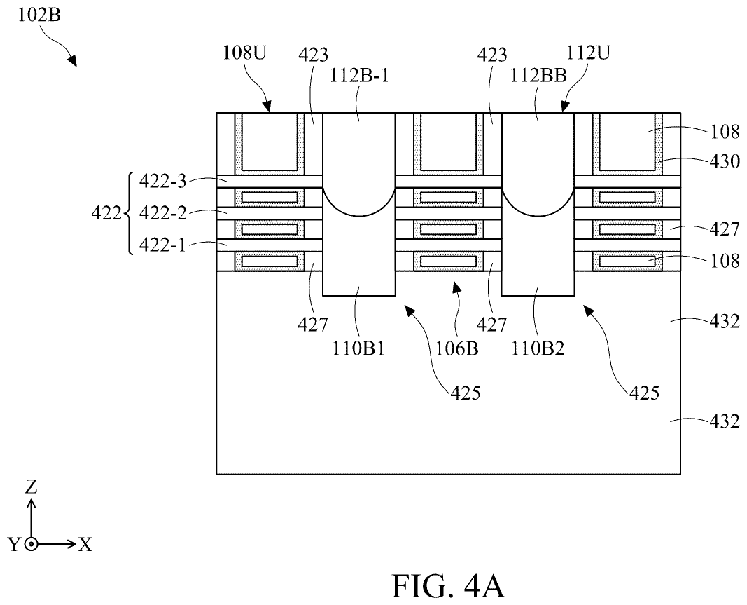

Semiconductor device 100 having transistors 102A, 102B can be formed on a substrate (not shown for simplicity) and can be isolated by shallow trench isolation (STI) regions. Each of transistors 102A, 102B can include a channel region 106A, 106B (shown in FIG. 4), e.g., a fin structures (a protrusion structure extended from the substrate), a gate structure 108 (including gate dielectric, gate electrode and/or gate function adjustment layers), and S/D structures 110A, 110B, and one or more S/D contact structure (MD) 112A, 112B. Some of the S/D contact structures 112A, 112B are coupled to a metal wire line or track 114, e.g., a power or a signal line, in a metallization level, e.g., the first metallization level (M0). In some implementations, an S/D contact structure 112A, 112B is coupled to the metal wire line 114 through an interconnection structure 116A, 116B, e.g., a via structure, a jumper structure, or other interconnect structures. In some implementations, the S/D contact structure 112B and the metal wire line 114 extend in different directions. In some implementations, the S/D contact structure 112B extend in a direction that is substantially perpendicular to a direction along which the metal wire line 114 extends.

Some of the S/D contact structures, e.g., 112B as shown in FIG. 1, includes a two-step structure-a first part (MD1) 112B-1 on the corresponding S/D structure 110B and a second part (MD2) 112B-2 on the first part 112B-1. The first part 112B-1 and the second part 112B-2 do not fully overlap with one another in the vertical z-axis direction (with respect to substrate of the transistor 102B), and have different dimensions in one or more the lateral directions in x-axis or y-axis. As shown in FIG. 1, as an illustrative example, the second part 112B-2 extends beyond or protrudes from the first part 112B-1 toward the S/D structure 110A of another transistor 102A so that the second part 112B-2 at least partially overlap with the wire line 114. The at least partial overlapping with the wireline 114 enables an easy coupling between the second part 112B-2 of the S/D contact structure 112B and the wireline 114, either directly or through an interconnect structure 116B.

In some implementations, the S/D structure 110B of transistor 102B is offset with respect to the wire line 114 and the S/D structure 110A of the transistor 102A overlaps with the wireline 114. The S/D structure 110A is not coupled to the wireline 114. The second part 112B-2 extends beyond and from the first part 112B-1 to a lateral point that at least partially overlap the wireline 114, and thus also at least partially overlaps with the S/D structure 110A of the transistor 102A. Note that the S/D contact structure 112B is coupled to the S/D structure 110B of the transistor 102B. Because of the two-step structure of S/D contact structure 112B, the second part 112B-2 is positioned on the first part 112B-1, such that the second part 112B-2 hangs or flies over the S/D structure 110A and there is a gap 118 between the second part 112B-2 and the S/D structure 110A. The gap 118 helps to maintain that the S/D structure 110A is isolated and insulated from the S/D contact structure 112B.

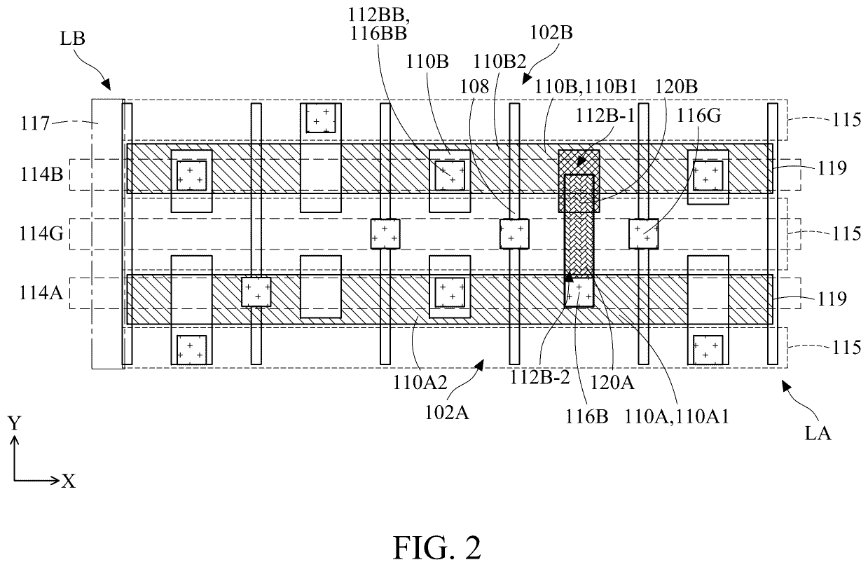

In some implementations, as shown in FIG. 2, the transistor 102A is arranged in a first line LA of transistors that each overlaps wire line 114A, the transistor 102B is arranged in a second line LB of transistors that each overlaps wire line 114B. The second part 112B-2 of the S/D contact structure 112B is coupled to the S/D structure 110B1 in the second line LB of transistors and extends in the y-axis direction from the first part 112B-1 to a point between the S/D structure 110A of the transistor 102A in the first line LA of transistors and the wire line 114A. Another S/D structure 110B2 of the transistor 102B is coupled to the wire line 114B through a one-step S/D contact structure 112BB an interconnect structure 116BB.

As show in FIG. 2, a wire line 114G is between the wire line 114A and the wireline 114B. The wire line 114G is coupled to the gate structure 108 through interconnect structure 116G. The second part 112B-2 of the S/D contact structure 112B passes the wire line 114G to reach the point that overlaps the wire line 114A.

In some implementations, the second part 112B-2 of the MID structure 112B extends alongside of the adjacent gate structure 108. For example, the second part 112B-2 extends in the y-axis direction between the S/D structure 110B1 of the transistor 102B and S/D structure 110A1 of the transistor 102A, which are both on the first side (illustratively shown as the right side on FIG. 2) of the gate structure 108. As shown in FIG. 2, the other S/D structure 110A2 of the transistor 102A is coupled to the write line 114A, and the S/D structure 110B1 of the transistor 102B is coupled to wireline 114A through the S/D contact structure 112B having the second part 112B-2 that extends from the second transistor line LB to the first transistor line LA. The second part 112B-2 includes a first end portion 120B coupled to the first part 112B-1 and a second end portion 120A that at least partially overlaps the wire line 114A. In some implementations, the second end portion 120A is coupled to the wire line 114A through interconnect structure 116B. The S/D structure 110A2 is coupled to the wireline 114A through interconnect structure 116A. In some implementations, interconnect structures 116A and 116B are substantially aligned to one another in the x-axis direction.

As further shown in FIG. 2, in some implementations, a gate isolation feature 115 is positioned between and separating a first gate structure 108 and a second gate structure 108. The gate structures 108 are aligned lengthwise with one another along the y-axis direction. The gate isolation features 115 extend along the x-axis direction. The gate isolation features 115 may be discrete portions between and separate adjacent gate structures 108. The active region 119 extends lengthwise along the x-axis direction. The active region 119 includes the channel region 106 and the S/D structure 110. A gate spacer 423 (shown in FIG. 4) extends along a sidewall of a gate structure 108. The gate isolation feature 115 interface the gate structure 108, and the gate spacer 423.

In some implementations, an isolation structure 117 extends along the y-axis direction. The gate isolation features 115 are each positioned between two active regions 119. The isolation structure 117 is disposed alongside end portions of the active regions 119.

In some implementations, the gate structures 108 are each disposed over the active regions 119, or more specifically, over the channel regions 106 of the active regions 119.

In some implementations, the gate isolation feature 115 is positioned over a dielectric layer that is positioned between the active regions 119 in the y-axis direction. And the gate isolation features 115 are each disposed between two portions of an interlayer dielectric (ILD) layer (not shown in FIG. 2) along the y-axis direction.

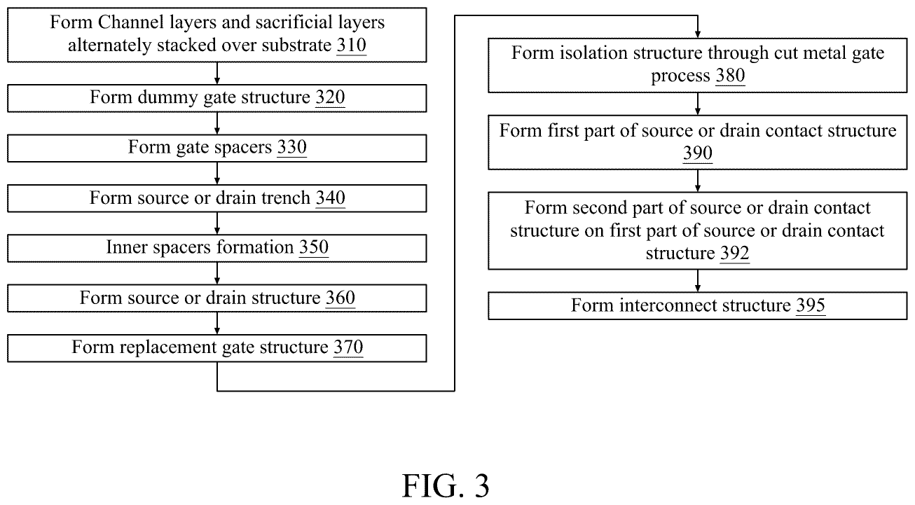

FIG. 3 shows an example manufacturing process 300 of forming example gate-all-around (GAA) transistors having a two-step S/D contact structure like those shown in FIGS. 1 and 2. FIG. 4 shows an example structure after the operation 390 has been completed.

In operation 310, channel layers and sacrificial layers are alternately stacked over a protrusion portion (referred to as “fin structure”) of a substrate, e.g., substrate 104 on FIG. 4. In some implementations, the channel layers and the sacrificial layers may have nanostructures on the fin structure.

The substrate can include a semiconductor material, such as silicon. In some implementations, the substrate includes a crystalline silicon substrate (e.g., wafer). In some implementations, the substrate includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, the substrate can be doped depending on design requirements (e.g., p-type substrate or n-type substrate). In some implementations, the substrate can be doped with p-type dopants (e.g., boron, indium, aluminum, or gallium) or n-type dopants (e.g., phosphorus or arsenic).

In some implementations, operation 310 includes forming shallow trench isolation (STI) regions 406, which provide electrical isolation between neighboring transistors 102A and 102B and/or neighboring active and passive elements (not shown) integrated with or deposited on the substrate. STI regions 406 can be made of a dielectric material. In some implementations, STI regions 406 can include silicon oxide, silicon nitride, silicon oxynitride, fluorine-doped silicate glass (FSG), a low-k dielectric material, and/or other suitable insulating materials. In some implementations, STI regions 406 can include a multi-layered structure.

In some implementations, the sacrificial layer includes etch selectivity with respect to the channel layers. For example, in a case the channel layers are silicon, the sacrificial layers are silicon germanium.

The channel layers and sacrificial layers can be patterned to form nanostructures on patterned portions of substrate 104. Embodiments of the nanostructures disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process.

As shown in FIGS. 4 and 4A, nanostructures can extend along an x-axis for transistors 102A, 102B (shown in FIG. 4A). In some implementations, nanostructures 422 and fin structure 408 can be disposed on substrate 404. Nanostructures 422 (sacrificial nanostructures already removed in the stage of FIGS. 4 and 4A) can include a set of channel nanostructures 422-1, 422-2, and 422-3, which can be in the form of nanosheets, nanowires, or nano-ribbons. Each of nanostructures 422 can act as a channel structure and form a part of channel region 106A, 106B underlying gate structures 108 of transistors 102A, 102B. In some implementations, nanostructures 422 and fin structures 408 can include semiconductor materials similar to or different from substrate 404. In some implementations, nanostructures 422 and fin structures 408 can include silicon. In some implementations, nanostructures 422 and fin structures 408 can include silicon germanium. The semiconductor materials of nanostructures 422 and fin structures 408 can be undoped or can be in-situ doped during their formation process.

In some implementations, as shown in FIG. 4A, channel region 106B include three channel nanostructures 422 under gate structures 108. Though three layers of nanostructures 422 are shown in FIG. 4A, it should be appreciated that transistors 102A, 102B each can have any number of nanostructures 422. In some implementations, transistors 102A, 102B can each have two to six layers of nanostructures 422.

In some implementations, nanostructures 422 can have a thickness along a Z-axis ranging from about 3 nm to about 8 nm. In some implementations, nanostructures 422 can have a width along a Y-axis ranging from about 15 nm to about 80 nm. In some implementations, a spacing between adjacent nanostructures 422 along a Z-axis can range from about 5 nm to about 20 nm.

It should be appreciated that the specific structural configurations of transistors 102A, 102B and the fabrication operations thereof are provided herein for illustrative purposes only, which does not limit the scope of the disclosure. The two-step S/D contact structures discussed herein can be formed in a MOL procedure on any type of transistor devices, which are all included in the scope of the disclosure.

In operation 320, a dummy gate structure is formed over the patterned nanostructures 422 and fin structures 408, referred to together as “fin structure” for brevity. The dummy gate stack may include a dummy dielectric layer on the sidewalls and top surface of the fin structure.

The dummy dielectric layer may include one or more dielectric materials such as silicon oxide (SiOx such as SiO2) and/or silicon nitride (SixNy such as Si3N4), among other examples. A deposition tool may be used to deposit the dummy dielectric layer using a PVD technique, an ALD technique, a CVD technique, an epitaxy technique, an oxidation technique, and/or another suitable deposition technique.

The dummy gate stack may include a dummy electrode layer over and/or on the dummy dielectric layer. The dummy electrode layer may include polysilicon and/or some other suitable material. The dummy dielectric layer and the dummy electrode layer may be patterned, e.g., etched, to define one or more dummy gate structures. A dummy gate structure is a temporary gate structure that is formed as a placeholder for a gate structure (e.g., a metal gate structure) of a transistor 102A, 102B.

In operation 330, gate spacers 423 are formed adjacent to the dummy gate structure. The gate spacers 423 are dielectric materials, e.g., SiN.

In operation 340, source or drain trenches 425 are formed in the fin structure on sides of the dummy gate structure. The source or drain trenches 425 may be formed by etching. In some implementations, both the nanostructure layers 422 and the sacrificial layers are removed from the source or drain trenches 425. In some implementations, only the sacrificial layers are removed from the source or drain trenches 425 and the nanostructure layers 422 may remain in the source or drain trenches 425. The nanostructure layers 422 between two source or drain trenches 425 will become channel regions 106A, 106B, and are also reference to as channel layers 106A, 106B.

In operation 350, inner spacer structures 427 are formed. The forming the inner spacer 427 may include recessing the sacrificial nanostructures through the source or drain trenches 425, and filling the recesses with a dielectric material(s).

In operation 360, source or drain (S/D) structures 110A, 110B are formed in the source or drain trenches 425. In some implementations, the source or drain structures 110A, 110B can be formed by an epitaxy process to grow epitaxial layers of semiconductor in the source or drain trenches 425. In some implementations, the source or drain structures 110A, 110B can be formed by doping the nanostructure layers 422 in the source or drain trenches 425.

In some implementations, S/D structures 110A, 110B can have any geometric shape, such as a polygon, an ellipse, and a circle. In some implementations, S/D structures 110A, 110B can include an epitaxially-grown semiconductor material, such as silicon (e.g., the same material as substrate 104). In some implementations, the epitaxially-grown semiconductor material can include an epitaxially-grown semiconductor material different from the material of substrate 404, such as silicon germanium and imparts a strain on the channel regions 106A, 106B under gate structures 108. Since the lattice constant of such epitaxially-grown semiconductor material is different from the material of substrate 104, the channel regions 106A, 106B can be strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some implementations, S/D structures 110A, 110B can include silicon and can be in-situ doped during an epitaxial growth process using n-type dopants, such as phosphorus and arsenic. In some implementations, S/D structures 110A, 110B can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some implementations, S/D structures 110A, 110B can include one or more epitaxial layers, where each epitaxial layer can have different compositions. In some implementations, S/D structure 110A, 110B can have a height along a Z-axis ranging from about 9 nm to about 60 nm.

In operation 370, the replacement gate structure 108 is formed. In some implementations, the replacement gate process includes replacing the dummy gate structures with gate structures 108, e.g., metal gate structures, of the transistors 102A, 102B.

For example, in the replacement gate process, an interlayer dielectric (ILD) layer may be deposited around the dummy gate structures. In some implementations, the ILD layer is deposited with a thickness of 100-400 nm (e.g., 200 nm) such that the ILD layer covers the dummy gate structures, and a planarization tool is used to perform a planarization operation (e.g., a CMP operation) such that the tops of the dummy gate structures are exposed and such that the top of the ILD layer is approximately at a same level with the tops of the dummy gate structure.

The ILD layer may include one or more dielectric materials such as silicon oxide (SiOx such as SiO2) and/or silicon nitride (SixNy such as Si3N4), among other examples. A deposition tool may be used to deposit the ILD layer using a PVD technique, an ALD technique, a CVD technique, an epitaxy technique, an oxidation technique, and/or another suitable deposition technique.

In some implementations, the ILD layer is a silicon nitride layer 430 or an additional silicon nitride layer 430 can be formed around the areas adjacent to the dummy gate structure or the areas adjacent to the to-be-formed source or drain contact structures.

One or more etch operations may be performed to remove the dummy gate structure to form a gate opening, through which portions of the fin structures, including the channel nanostructure layers and the sacrificial nanostructure layers, are exposed.

The sacrificial nanostructure layers within the gate opening are selectively removed by etching, while the channel layers 106A, 106B and the inner spacers 427 remain.

After the sacrificial nanostructure layers are removed from the gate opening, the gate structure 108 is formed in the gate opening. In some implementations, the gate structure 108 wrap around the channel layers 106A, 106B.

A gate structure 108 may include a conformal stack of one or more of an interfacial layer, a gate dielectric layer, or a work function metal layer, among other examples. A gate structure may further include a gate electrode layer on the conformal stack.

The interfacial layer can include silicon oxide formed by a deposition process or an oxidation process. In some implementations, the interfacial layer can have a thickness ranging from about 0.1 nm to about 1.5 nm. For example, the interfacial layer may include an oxide layer that is formed from a chemical reaction with the surface of the channel layers 106A, 106B. For example, a chemical oxidation process using ozone (03) in combination with hydrofluoric acid (HF) and/or hydrochloric acid (HCl) may be used to oxidize the exposed portions of the channel layers 106A, 106B in the gate opening.

Additionally or alternatively, the interfacial layer may be formed by a thermal oxidation process, such as by rapid thermal anneal (RTA).

In some implementations, the interfacial layer is formed by deposition, and a deposition tool may be used to deposit the interfacial layer using an ALD technique, a CVD technique, and/or another suitable deposition technique.

The gate dielectric layer may include a high dielectric constant (high-k) dielectric material having a dielectric constant that is greater than approximately 3.9. Such high-k dielectric materials may include hafnium oxide (HfOx such as HfO2), aluminum oxide (AlxOy such as Al2O3), zirconium oxide (ZrOx such as ZrO2), hafnium zirconium oxide (HfZrOx), hafnium silicon oxide (HfSiOx), lanthanum oxide (LaxOy such as La2O3), and/or titanium oxide (TiOx such as TiO2), among other examples. Additionally and/or alternatively, the gate dielectric layer may include one or more low dielectric constant (low-k) dielectric materials such as silicon oxide (SiOx such as SiO2).

In some implementations, the gate dielectric layer is formed by deposition, and a deposition tool may be used to deposit the gate dielectric layer using an ALD technique, a CVD technique, and/or another suitable deposition technique. In some implementations, the gate dielectric layer is formed to a thickness that is included in a range of approximately 1 nanometer to approximately 4 nanometers. However, other values and ranges are within the scope of the present disclosure.

After the gate dielectric layer is deposited, an anneal may be performed on the gate dielectric layer to cure bulk defects in the gate dielectric layer. The anneal may be performed in an environment that contains hydrogen gas, oxygen gas, and/or nitrogen gas, among other examples.

The work function metal layer may include one or more metals and/or one or more metal alloys that are included for tuning the work function of the gate structure 108. In some implementations, a work function metal layer of an n-type transistor may include an n-type metal that tunes or adjusts the work function of the gate structure 108 of the n-type transistor near the conduction band of the material of the channel layers 106A, 106B. Examples of such n-type metals include titanium aluminum (TiAl), titanium aluminum carbon (TiAlC), and/or another aluminum-containing metal, among other examples. In some implementations, a work function metal layer of a p-type transistor may include one or more p-type metals, such as titanium nitride (TiN), tungsten nitride (WN), and/or another metal having a work function that is greater than approximately 4.7 eV, among other examples. The p-type metal may be included to tune the work function of the p-type transistor such that the work function is adjusted close to the valance band of the material of the channel layers 106A, 106B.

In some implementations, the work function metal layer is formed by deposition, and a deposition tool may be used to deposit the work function metal layer using an ALD technique, a CVD technique, and/or another suitable deposition technique. In some implementations, the work function metal layer is formed to a thickness that is included in a range of approximately 2 nanometers to approximately 8 nanometers. However, other values and ranges are within the scope of the present disclosure.

The gate electrode layer may include one or more metals, such as tungsten (W), titanium (Ti), and/or copper (Cu), among other examples. In some implementations, the gate electrode layer is formed by deposition, and a deposition tool may be used to deposit the gate electrode layer using an ALD technique, a CVD technique, and/or another suitable deposition technique. In some implementations, a planarization tool is used to planarize the gate structures 108 after the gate electrode layer is deposited.

In operation 380, an isolation structure or line cut structure 432 is formed. For example, in a cut metal gate CMG process, a patterned hard mask layer is formed. The patterned hard mask layer has an opening defining a line-cut to be formed. For example, the opening aligns to a designated portion of the gate structure 108 between two fin structures, which will be removed later. In some implementations, portions of the gate structure 108, the gate spacer 423, the ILD layer 430 are removed through the opening in the hard mask to form a line cut opening. A dielectric material is filled in the line cut opening to form the line cut structure 432.

In operation 390, a first part (MD1) of a two-step S/D contact structure or a one-step S/D contact structure (MD1) are formed. In some implementations, the first part (MD1) of a two-step S/D contact structure and the one-step S/D contact structure (MD1) are formed in a same level, which are also referred together as the MID1 structure for descriptive purposes. For example, S/D contact trenches 434 are made, e.g., through a trench etch, in the silicon nitride layer 430. Therefore, designated S/D structures 110A, 110B are exposed within the S/D contact trenches. The trench etch may include a selective wet etch, a selective dry etch, and/or a combination thereof. As an example, the trench etch includes a plasma dry etching process using a fluorine-based chemistry, such as CF4, SF6, CH2F2, CHF3, and/or C2F6.

Subsequently, a conductive layer or S/D contact metal is deposited in the S/D contact trenches 434 to form the MD1 structures (including a first part of a two-step S/D contact structure or a one-step S/D contact structure). As shown in FIGS. 4 and 4A, the MD1 structures 112B-1 and 112BB are formed on S/D structures 110B1 and 110B2, respectively. The S/D contact metal of the MD1 structures extends within the S/D contact trenches 434 to contact S/D structures 110B1, 110B2. The S/D contact metal may include copper (Cu), aluminum (Al), tungsten (W), copper magnesium (CuMn), copper aluminum (CuAl) or copper silicon (CuSi), and/or other suitable conductive material. The S/D contact metal may be formed by PVD, CVD, metal-organic chemical vapor deposition (MOCVD), or plating. In some implementations, a CMP process is performed to remove excessive the S/D contact metal.

In some implementations, the MD1 structures are substantially at a same level, e.g., coplanar, with one another. That is, an upper surface of the first part 112B-1 of the two-step S/D contact structure 112B and an upper surface of the one step S/D contact structure 112BB is substantially coplanar with one another.

In some implementations, an upper surface 112U of the MD1 structures (including first part 112B-1 of the two-step S/D contact structure 112B or the one step S/D contact structure 112BB) is substantially at a same level as or higher than an upper surface 108U of the gate structure 108.

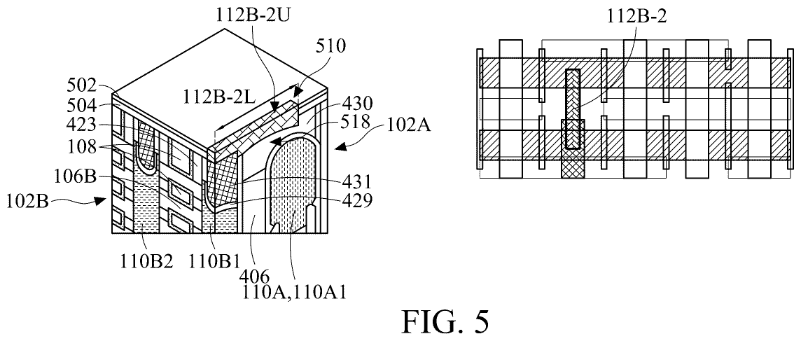

In operation 392, a second part (MD2) 112B-2 of the two-step S/D contact structure 112B is formed on the first part (MD1) 112B-1 of the two-step S/D contact structure 112B. Referring also to FIG. 5, for example, an inter-layer dielectric ILD layer 502 and an etch stop layer 504 are formed on the first part 112B-1 of the two-step S/D structure 112B. The etch stop layer 504 is a dielectric material different from the ILD layer 502, and can be one or more of aluminum oxide (AlOx, AlON), silicon carbide (SiC), silicon nitride (SiN), hafnium oxide (HfO2), or other suitable dielectric material like boron nitride, silicon boron nitride, silicon carbon boron nitride, or a combination thereof.

The ILD layer 502 can be include a dielectric material deposited using a deposition method suitable for flowable dielectric materials. For example, flowable silicon oxide can be deposited using flowable chemical vapor deposition (FCVD). In some implementations, the dielectric material of the ILD layer 502 can include silicon oxide.

The ILD layer 502 and the etch stop layer 504 are patterned to form an flyer trench 510. As shown in FIG. 5 as an illustrative example, the flyer trench 510 exposes the underlying first part 112B-1 and laterally extends from the first part 112B-1, over the STI structure 406 to a point that overlaps the S/D structure 110A of the transistor 102A. The S/D structure 110A of the transistor 102A can be a same type of semiconductor structure, N-type or P-type, as the S/D structure 110B of the transistor 102B, or may be a different type of semiconductor structure from the S/D structure 110B of the transistor 102B.

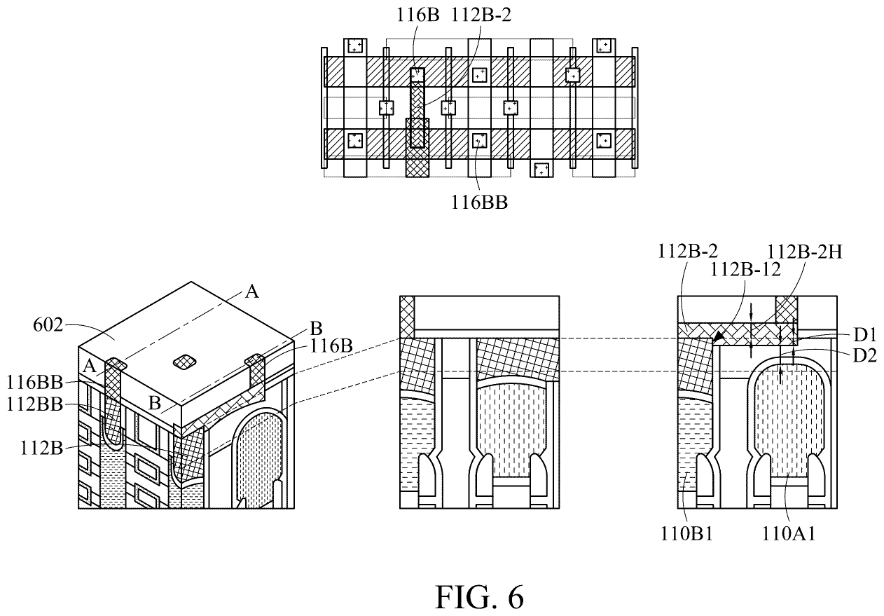

In some implementations, the flyer trench 510 vertically extends or recesses into the silicon nitride layer 430 (see also FIG. 6) due to over etching. A depth of the recess of the flyer trench 510 can be in a range of 0-10 nm. As such, the flyer trench 510 does not recess too deeply to reach the S/D structure 110A of the transistor 102A, and a gap space 518 is maintained between the flyer trench 510 and the S/D structure 110A of the transistor 102A. In some implementations, the gate spacer 423 helps to make sure that the flyer trench 510 may not extend into the gate structure 108.

The etch of the flyer trench 510 may include a selective wet etch, a selective dry etch, and/or a combination thereof. As an example, the trench etch includes a plasma dry etching process using a fluorine-based chemistry, such as CF4, SF6, CH2F2, CHF3, and/or C2F6.

Subsequently, a conductive layer or S/D contact metal is deposited in the flyer trench 510 to form a second part of a two-step S/D structure. The S/D contact metal may include copper (Cu), aluminum (Al), tungsten (W), copper magnesium (CuMn), copper aluminum (CuAl) or copper silicon (CuSi), and/or other suitable conductive material. In some implementations, the S/D contact metal of the second part 112B-2 includes a same conductive material as those of the first part 112B-1, which does not limit the scope of the disclosure. The S/D contact metal of the second part 112B-2 may be formed by PVD, CVD, metal-organic chemical vapor deposition (MOCVD), or plating. In some implementations, a CMP process is performed to remove excessive the S/D contact metal.

In some implementations, an upper level 112B-2U of the of the second part 112B-2 of the S/D contact structure 112B is at a level higher than an upper surface 108U of the gate structure 108.

In the description herein, the second part 112B-2 of S/D contact structure 112B may also be referred to as a “S/D contact flyer.” However, as we discussed herein, in some implementations, a S/D contact flyer may not be connected to any S/D structure and may not be part of a S/D contact structure. In some implementations, the second part 112B-2 of S/D contact structure 112B can have a height or thickness 112B-2H (FIG. 6) along a z-axis ranging from about 6 nm to about 12 nm above the upper surface 108U of the gate structure 108. If the height difference value is smaller than 6 nm, resistance value will increase. If the height difference value is greater than 12 nm, parasitic capacitance will increase.

In some implementations, because the flyer trench 510 recess into the silicon nitride layer 430, the second part 112B-2 extends into the silicon nitride layer 430 for a depth D1 (FIG. 6) in a range of 0-10 nm. In this case, the second part 112B-2 and the first part 112B-1 laterally interface with one another through the interface 112B-12.

In some implementations, a distance D2 (FIG. 6) of the gap 118 between the second part 112B-2 of S/D contact structure 112B and the S/D structure 110A of the transistor 102A is equal to or greater than 4.5 nm, which ensures the electrical isolation between the second part 112B-2 and the S/D structure 110A.

A length 112B-2L of the second part 112B-2 is in a range of 8-200 nm.

In some implementations, the ILD layer 502 can be one or more of SiOCN or a high-K compound dielectric material or other suitable dielectric materials.

In some implementations, a metal silicide layer 429 is disposed between the S/D structure 110 and the S/D contact structure 112. An electrical conductivity of the metal silicide layer 429 is between an electrical conductivity of the S/D structure 110 and an electrical conductivity of the S/D contact structure 112. In some implementations, the metal silicide layer 429 includes a curved profile.

In some implementations, an electrical conductivity of the metal silicide layer 429 is greater than an electrical conductivity of the S/D structure 110. In some implementations, an electrical conductivity of the S/D contact structure 112 is greater than the electrical conductivity of the metal silicide layer 429.

In some implementations, the S/D contact structure 112 is spaced apart from the adjacent dielectric layer, e.g., an ILD layer or the STI region 406, by a metal-containing interface layer 431. The interface layer 431 includes a material composition different from a material composition of the S/D contact structure 112.

Referring back to FIG. 3, in operation 395, interconnect structures are formed on S/D contact structures 102B, 102BB. Referring to FIG. 6, an ILD layer 602 is formed on the S/D contact structures 112B, 112BB. Interconnect structures 116BB, 116B are formed in trenches/holes formed in the ILD layer 602 and on the respective S/D contact structures 112BB, 112B. In some implementations, the upper levels of the interconnect structures 116BB, 116B are substantially at a same level, e.g., coplanar, as one another. Because of the height differences between the S/D contact structure 112BB having a one-step structure and the S/D contact structure 112B having a two-step structure, e.g., 6-12 nm difference, the corresponding interconnect structures 116BB, 116B have different height/thickness values. For example, the interconnect structure 116BB on the S/D contact structure 112BB having a one-step structure includes a height/thickness in a range of 6-18 nm, while the interconnect structure 116B on the S/D contact structure 112B having a two-step structure includes a height/thickness in a range of 12-30 nm.

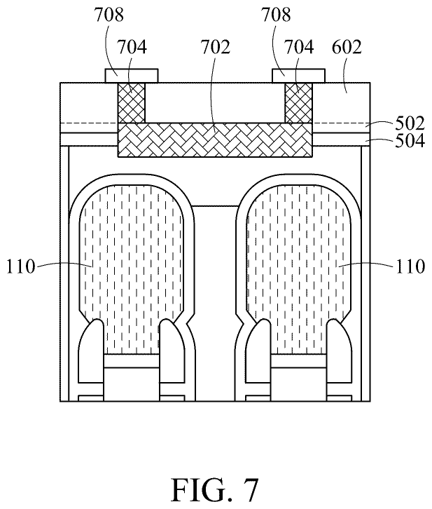

In some implementations, the operation 392 includes forming a wire routing structure on a level over a S/D structure. As shown in FIG. 7, wire routing structure 702 is formed in the ILD layer 502 and immediately over the S/D structures 110. The wire routing structure 702 is spaced apart from the S/D structures 110 and there is no S/D contact structures on the S/D structures 110. That is, the wire routing structure 702 is not connected to any S/D contact structure and may not connect to any S/D structure. As shown in FIG. 7, one or more interconnect structures 704 are formed on the wire routing structure 702, which connect the wire routing structure 702 to metal features on a higher level, e.g., the first metallization level MO. For example, the wire routing structure 702 may extend between two separate wire lines 708 on the metallization level, and are connected to each of the wire lines 708 through respective interconnect structures 704. In some implementations, the wire lines 708 may each overlap a S/D structure 110.

FIG. 6 shows an example implementation that a S/D contact flyer structure (MD2) 112B-2 is connected to one first part (MD1) 112B-1 of a two-step S/D contact structure 112B, flies over one S/D structure (EPI) 110A, and is connected to one interconnect structure (VD) 116B. This illustrative example does not limit the scope of the disclosure. As shown in FIG. 7, a S/D contact flyer structure (MD2) can be configured to be connected to various number of first part (MD1) of a two-step S/D contact, to fly over various number of S/D structures (EPI), and to be connected to various number of interconnect structures (VD).

As described in greater detail above, some implementations described herein provide a semiconductor structure. A semiconductor structure includes: a substrate; a gate structure on the substrate; a first source or drain (S/D) structure of a first transistor on the substrate and adjacent to the gate structure; and a first S/D contact structure on the first S/D structure, the first S/D contact structure including a first part on the first S/D structure and a second part on the first part and extending laterally beyond the first part.

In some implementations, a semiconductor structure includes: a substrate; a gate structure on the substrate; a first source or drain (S/D) structure of a first transistor on the substrate and adjacent to the gate structure; a first S/D contact structure on the first S/D structure; a first metallization level including a first wire line and second wire line; and a metal flyer structure on a level immediately over the first S/D contact structure and below the first metallization level.

In some implementations, a method includes: forming a first source/drain (S/D) structure and a second S/D structure on a substrate; depositing a dielectric layer on the first S/D structure and the second S/D structure; forming a gate structure between the first S/D structure and the second S/D structure and at least partially in the dielectric layer; forming a first metal contact structure on the first S/D structure and in the dielectric layer; and forming a second metal contact structure on the first metal contact structure and extending laterally beyond the first metal contact structure toward the second S/D structure, wherein the second metal contact structure is separated from the second S/D structure by a gap in a vertical direction.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several implementations so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the implementations introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a gate structure on the substrate;
a first source or drain (S/D) structure of a first transistor on the substrate and adjacent to the gate structure; and
a first S/D contact structure on the first S/D structure, the first S/D contact structure including a first part on the first S/D structure and a second part on the first part and extending laterally beyond the first part.

2. The semiconductor structure of claim 1, wherein an upper surface of the first part of the first S/D contact structure is substantially at a same level as an upper surface of the gate structure or is higher than the upper surface of the gate structure.

3. The semiconductor structure of claim 1, comprising a first wire line that is offset from the first S/D structure, wherein the second part of the first S/D contact structure expends to a point that at least partially overlaps the first wireline.

4. The semiconductor structure of claim 1, comprising a second S/D structure of a second transistor different from the first transistor, wherein the second part of the first S/D contact structure expends to a point that at least partially overlaps the second S/D structure.

5. The semiconductor structure of claim 4, wherein the second part of the first S/D contact structure is separated from the second S/D structure by a gap.

6. The semiconductor structure of claim 5, wherein a distance between the second part of the first S/D contact structure and the second S/D structure is equal to or greater than 4.5 nm.

7. The semiconductor structure of claim 1, comprising:
a second S/D structure of a second transistor different from the first transistor;
a second S/D contact structure on the second S/D structure; and
a first wire line,
wherein the second part of the first S/D contact structure and the second S/D structure are connected to the first wire line.

8. The semiconductor structure of claim 7, wherein the second S/D is substantially at a same level as the first part of the first S/D contact structure.

9. The semiconductor structure of claim 7, wherein the second part of the first S/D contact structure is connected to the first wire line through a first interconnect structure, the second S/D contact structure is connected to the first wire line through a second interconnect structure, and the second interconnect structure includes a greater height than the first interconnect structure.

10. The semiconductor structure of claim 1, wherein the first part and the second part interfaces with one another in a lateral direction.

11. The semiconductor structure of claim 1, wherein an upper surface of the gate structure and an upper surface of the first part of the first S/D contact structure is substantially at a same level.

12. The semiconductor structure of claim 1, wherein an upper surface of the first part of the first S/D contact structure is higher than an upper surface of the gate structure.

13. The semiconductor structure of claim 1, wherein the second part of the first S/D contact structure extends alongside the gate structure.

14. The semiconductor structure of claim 1, comprising:
a second wire line that overlaps the first S/D structure and a second S/D structure of the first transistor;
a second S/D contact structure on the second S/D structure and connected to the second wireline,
wherein the second S/D contact structure is substantially at a same level as the first part of the first S/D contact structure.

15. The semiconductor structure of claim 14, wherein the second part of the first S/D contact structure is connected to the first wire line through a first interconnect structure, the second S/D contact structure is connected to the second wire line through a second interconnect structure, and the second interconnect structure includes a greater height than the first interconnect structure.

16. The semiconductor structure of claim 1, wherein the first S/D structure is in an active region extending in a first direction, and the gate structure is disposed over the active region and extending in a second direction that crosses the first direction.

17. A semiconductor structure, comprising:
a substrate;
a gate structure on the substrate;
a first source or drain (S/D) structure of a first transistor on the substrate and adjacent to the gate structure;
a first S/D contact structure on the first S/D structure;
a first metallization level including a first wire line and second wire line; and
a metal flyer structure on a level immediately over the first S/D contact structure and below the first metallization level.

18. The semiconductor structure of claim 17, wherein the metal flyer structure is not directly connected to the first S/D structure, and the metal flyer structure extends between the first wire line and the second wire line.

19. A method, comprising
forming a first source/drain (S/D) structure and a second S/D structure on a substrate;
depositing a dielectric layer on the first S/D structure and the second S/D structure;
forming a gate structure between the first S/D structure and the second S/D structure and at least partially in the dielectric layer;
forming a first metal contact structure on the first S/D structure and in the dielectric layer; and
forming a second metal contact structure on the first metal contact structure and extending laterally beyond the first metal contact structure toward the second S/D structure, wherein the second metal contact structure is separated from the second S/D structure by a gap in a vertical direction.

20. The method of claim 19, comprising:
forming a third S/D structure;
forming a S/D contact structure on the third S/D structure;
forming a first interconnect structure on the S/D contact structure; and
forming a second interconnect structure on the second metal contact structure, the second interconnect structure substantially aligned with the first interconnect structure in a lateral direction.
